(19) United States
(12) Patent Application Publication
(10) Pub. No.: US 2018/0337202 A1
(43) Pub. Date: Nov. 22, 2018

(54) TFT SUBSTRATE MANUFACTURING METHOD

(71) Applicant: Shenzhen China Star Optoelectronics Technology Co., Ltd, Shenzhen City (CN)

(72) Inventor: Qiming Gan, Shenzhen City (CN)

(21) Appl. No.: 15/326,648

(22) PCT Filed: Dec. 15, 2016
(86) PCT No.: PCT/CN2016/110072

§ 371 Date: Jan. 17, 2017

(30) Foreign Application Priority Data
Aug. 17, 2016 (CN) 201610685365.1

(51) Int. Cl. H01L 27/12; H01L 29/66; H01L 21/027; H01L 21/311; H01L 21/3213; H01L 21/308

(52) U.S. Cl. CPC H01L 27/1288; H01L 29/66765; H01L 29/66969; H01L 21/308; H01L 21/31144; H01L 21/32139; H01L 21/0273

(57) ABSTRACT

The present invention provides a TFT substrate manufacturing method, which uses a half tone mask or a gray tone mask to pattern a passivation layer so that a pixel electrode via and a groove-patterned passivation layer can be formed with one mask. And, a transparent conductive material can be deposited on and in compliance with the passivation layer to form a pixel electrode. The pixel electrode requires no mask for patterning, and entire manufacture of a TFT substrate requires only three masks, without the need of indium tin oxide lift-off technique, making the difficulty of manufacturing low and efficiency high.

### BACKGROUND OF THE INVENTION

### 1. Field of the Invention

The present invention relates to the field of display technology, and more particular to a thin-film transistor (TFT) substrate manufacturing method.

### 2. The Related Arts

With the progress of the display technology, flat panel display devices, such as liquid crystal display (LCD), due to various advantages, such as high image quality, low power consumption, thin device body, and wide range of applications, have been widely used in various consumer electronic products, including mobile phones, televisions, personal digital assistants, digital cameras, notebook computers, and desktop computers, making them the main stream of display devices.

A liquid crystal display panel is generally made up of a color filter (CF) substrate, a thin film transistor (TFT) substrate, liquid crystal (LC) interposed between the CF substrate and the TFT substrate, and sealant and is generally manufactured with a process involving an anterior stage of array engineering (involving thin film, photolithography, etching, and film peeling), an intermediate stage of cell engineering (involving lamination of the array substrate and the CF substrate), and a posterior stage of module assembly (involving combining a drive integrated circuit (IC) and a printed circuit board). Among these stages, the anterior stage of array engineering generally involves the formation the array substrate for controlling the movement of liquid crystal molecules; the intermediate stage of cell engineering generally involves filling liquid crystal between the array substrate and the CF substrate; and the posterior stage of module assembly generally involves the combination of the drive IC and the printed circuit board for driving the liquid crystal molecules to rotate for displaying images.

Contemporary methods for manufacturing TFT substrates have evolved from the early 7 mask based techniques to 4 mask based techniques. The four masks are respectively used in formation of a patterned gate terminal, patterned active layer and source/drain terminals, a via in a pixel electrode, and a patterned pixel electrode. Concurrent with this, 3 mask based techniques have been started using in some products for further simplifying the manufacturing operations of TFT substrates, shortening manufacturing time, and increasing manufacturing efficiency. Compared to the 4 mask based technique, the 3 mask based technique can save one more mask used and thus shortening the manufacturing time, showing obvious advantages. However, the 3 mask based technique that is currently used is much more difficult than the 4 mask based technique, because the indium tin oxide (ITO) lift-off operations that are widely used in the 3 mask based technique have great difficulty, making the 3 mask based technique also showing great difficulty.

### SUMMARY OF THE INVENTION

An objective of the present invention is to provide a thin film transistor (TFT) substrate manufacturing method, which helps reduce the number of masks involved in a process of manufacturing a TFT substrate and thus increase the efficiency of manufacturing the TFT substrate.

To achieve the above objective, the present invention provides a TFT substrate manufacturing method, which comprises the following steps:

Step 1: providing a base plate, depositing a first metal layer on the base plate, and using one mask to pattern the first metal layer so as to form a gate electrode and a gate line electrically connected with the gate electrode;

Step 2: depositing a gate insulation layer on the base plate, the gate electrode, and the gate line;

Step 3: depositing a semiconductor layer and a second metal layer on the gate insulation layer and using one mask to simultaneously pattern the semiconductor layer and the second metal layer with one mask so as to form an active layer on the gate insulation layer that is located above the gate electrode, a source electrode and a drain electrode that are respectively in contact engagement with two ends of the active layer, and a data line electrically connected with the source electrode;

Step 4: depositing a passivation layer on the source electrode, the drain electrode, the data line, the active layer, and the gate insulation layer;

Step 5: coating photoresist on the passivation layer to form a photoresist layer, using one mask to pattern the photoresist layer to completely remove the photoresist layer corresponding to and located above a part of the drain electrode and a margin of an area of a pixel electrode to be formed and expose portions of the passivation layer located above the part of the drain electrode and the margin of the area of the pixel electrode to be formed and also to reduce a thickness of a portion of the photoresist layer in the area of the pixel electrode to be formed to form photoresist grooves extending in multiple different directions;

Step 6: using the remaining photoresist layer as a shield to conduct a first etching operation to completely remove the passivation layer that is located above the drain electrode and is not shielded by the photoresist layer to expose the part of the drain electrode and at the same time, also to partly remove the passivation layer in the margin of the area of the pixel electrode to be formed to reduce a thickness of a part of the passivation layer in the margin of the area of the pixel electrode to be formed, and subsequently conducting a first photoresist ashing operation to completely remove the photoresist layer in each of the photoresist grooves and reduce a thickness of the photoresist layer on two sides of each of the photoresist grooves;

Step 7: using the remaining photoresist layer as a shield to conduct a second etching operation to reduce a thickness of the passivation layer in each of the photoresist grooves so as to form passivation layer grooves extending in multiple different directions and at the same time, to partly or completely remove the passivation layer remaining in the margin of the area of the pixel electrode to be formed to form a pixel spacing groove at the margin of the area of the pixel electrode to be formed; and

Step 8: completely removing the remaining photoresist layer and depositing a transparent conductive layer on the passivation layer and the exposed drain electrode, wherein the transparent conductive layer is interrupted at the pixel spacing groove during deposition to form a pixel electrode in contact engagement with the drain electrode, the pixel electrode showing a corrugated configuration in compliance with the passivation layer grooves.

Step 3 comprises:

Step 31: coating photoresist on the second metal layer, providing a gray tone mask or a half tone mask to subject the photoresist to patterning in order to remove a portion of the photoresist on a location of a channel zone of a TFT to be formed and remove all the photoresist located outside areas of the TFT to be formed and the data line, while preserving all the photoresist in areas of a source electrode and a drain electrode of the TFT to be formed and the data line;

Step 32: conducting a first etching operation to remove the second metal layer and the semiconductor layer that is not covered by the photoresist;

Step 33: conducting an ashing operation of the photoresist on the channel zone of the TFT to be formed to remove all the photoresist on the channel zone of the TFT to be formed; and

Step 34: subsequently conducting a second etching operation to remove the second metal layer on the channel zone of the TFT to be formed to form the active layer, the source electrode and the drain electrode respectively in contact engagement with the two ends of the active layer, and the data line electrically connection with the source electrode.

The mask used in Step 5 for exposure of the photoresist layer is a gray tone mask or a half tone mask.

The active layer comprises a material that comprises amorphous silicon, poly-silicon, or an oxide semiconductor.

The passivation layer that is located above the drain electrode in the pixel spacing groove and at one side that is close to the source electrode has a taper angle that is greater than 90 degrees, while the passivation layer at one side that is distant from the source electrode has a taper angle that is smaller than 90 degrees; the passivation layer on two sides of a portion of the pixel spacing groove at a location other than being above the drain electrode have a taper angle greater than 90 degrees.

In Step 8, the transparent conductive layer comprises a material that comprises indium tin oxide (ITO).

The first metal layer and the second metal layer comprise a material that comprises one or a combination of multiple ones of aluminum, molybdenum, and copper.

The gate insulation layer and the passivation layer comprise a material that comprises one or a combination of multiple ones of silicon oxide and silicon nitride.

The base plate comprises a transparent glass plate or a transparent plastic plate.

The present invention also provides a TFT substrate manufacturing method, which comprises the following steps:

Step 1: providing a base plate, depositing a first metal layer on the base plate, and using one mask to pattern the first metal layer so as to form a gate electrode and a gate line electrically connected with the gate electrode;

Step 2: depositing a gate insulation layer on the base plate, the gate electrode, and the gate line;

Step 3: depositing a semiconductor layer and a second metal layer on the gate insulation layer and using one mask to simultaneously pattern the semiconductor layer and the second metal layer with one mask so as to form an active layer on the gate insulation layer that is located above the gate electrode, a source electrode and a drain electrode that are respectively in contact engagement with two ends of the active layer, and a data line electrically connected with the source electrode;

Step 4: depositing a passivation layer on the source electrode, the drain electrode, the data line, the active layer, and the gate insulation layer;

Step 5: coating photoresist on the passivation layer to form a photoresist layer, using one mask to pattern the photoresist layer to completely remove the photoresist layer corresponding to and located above a part of the drain electrode and a margin of an area of a pixel electrode to be formed and expose portions of the passivation layer located above the part of the drain electrode and the margin of the area of the pixel electrode to be formed and also to reduce a thickness of a portion of the photoresist layer in the area of the pixel electrode to be formed to form photoresist grooves extending in multiple different directions;

Step 6: using the remaining photoresist layer as a shield to conduct a first etching operation to completely remove the passivation layer that is located above the drain electrode and is not shielded by the photoresist layer to expose the part of the drain electrode and at the same time, also to partly remove the passivation layer in the margin of the area of the pixel electrode to be formed to reduce a thickness of a part of the passivation layer in the margin of the area of the pixel electrode to be formed, and subsequently conducting a first photoresist ashing operation to completely remove the photoresist layer in each of the photoresist grooves and reduce a thickness of the photoresist layer on two sides of each of the photoresist grooves;

Step 7: using the remaining photoresist layer as a shield to conduct a second etching operation to reduce a thickness of the passivation layer in each of the photoresist grooves so as to form passivation layer grooves extending in multiple different directions and at the same time, to partly or completely remove the passivation layer remaining in the margin of the area of the pixel electrode to be formed to form a pixel spacing groove at the margin of the area of the pixel electrode to be formed; and

Step 8: completely removing the remaining photoresist layer and depositing a transparent conductive layer on the passivation layer and the exposed drain electrode, wherein the transparent conductive layer is interrupted at the pixel spacing groove during deposition to form a pixel electrode in contact engagement with the drain electrode, the pixel electrode showing a corrugated configuration in compliance with the passivation layer grooves;

wherein the mask used in Step 5 for exposure of the photoresist layer is a gray tone mask or a half tone mask; and

wherein the active layer comprises a material that comprises amorphous silicon, poly-silicon, or an oxide semiconductor.

The efficacy of the present invention is that the present invention provides a TFT substrate manufacturing method, which uses a half tone mask or a gray tone mask to pattern a passivation layer so that a pixel electrode via and a groove-patterned passivation layer can be formed with one mask. And, a transparent conductive material can be deposited on and in compliance with the passivation layer to form a pixel electrode. The pixel electrode requires no mask for patterning, and entire manufacture of a TFT substrate requires only three masks, without the need of indium tin oxide lift-off technique, making the difficulty of manufacturing low and efficiency high.

### BRIEF DESCRIPTION OF THE DRAWINGS

For better understanding of the features and technical contents of the present invention, reference will be made to the following detailed description of the present invention and the attached drawings. However, the drawings are provided only for reference and illustration and are not intended to limit the present invention.

In the drawings:

FIG. 1 is a cross-sectional view illustrating Step 1 of a TFT substrate manufacturing method according to the present invention;

FIG. 2 is a cross-sectional view illustrating Step 2 of the TFT substrate manufacturing method according to the present invention;

FIG. 3 is a cross-sectional view illustrating Step 3 of the TFT substrate manufacturing method according to the present invention;

FIG. 4 is a cross-sectional view illustrating Step 4 of the TFT substrate manufacturing method according to the present invention;

FIG. 5 is a cross-sectional view illustrating Step 5 of the TFT substrate manufacturing method according to the present invention;

FIG. 6 is a cross-sectional view illustrating Step 6 of the TFT substrate manufacturing method according to the present invention;

FIG. 7 is a cross-sectional view illustrating Step 7 of the TFT substrate manufacturing method according to the present invention;

FIG. 8 is a cross-sectional view illustrating Step 8 of the TFT substrate manufacturing method according to the present invention;

FIG. 9 is a top plan view illustrating Step 1 of the TFT substrate manufacturing method according to the present invention;

FIG. 10 is a top plan view illustrating Step 3 of the TFT substrate manufacturing method according to the present invention;

FIG. 11 is a top plan view illustrating Step 8 of the TFT substrate manufacturing method according to the present invention; and

FIG. 12 is a flow chart illustrating the TFT substrate manufacturing method according to the present invention.

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

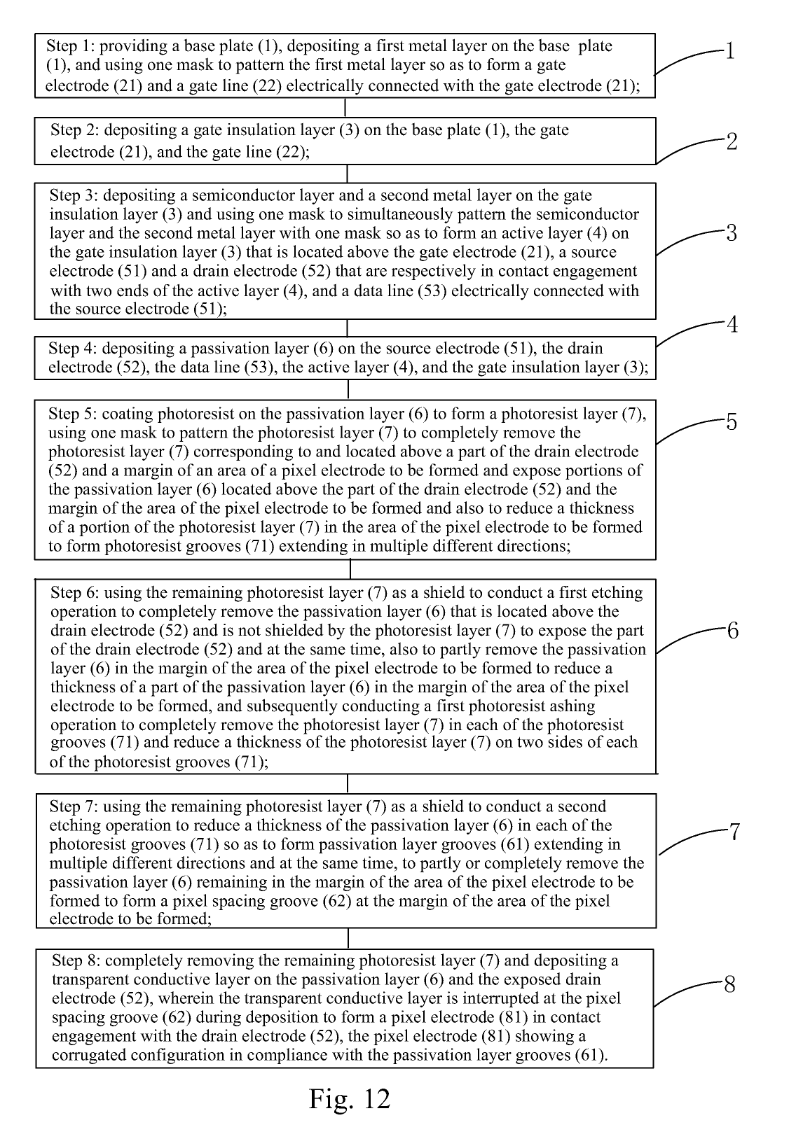

Referring to FIG. 12, the present invention provides thin film transistor (TFT) substrate manufacturing method, comprising the following steps:

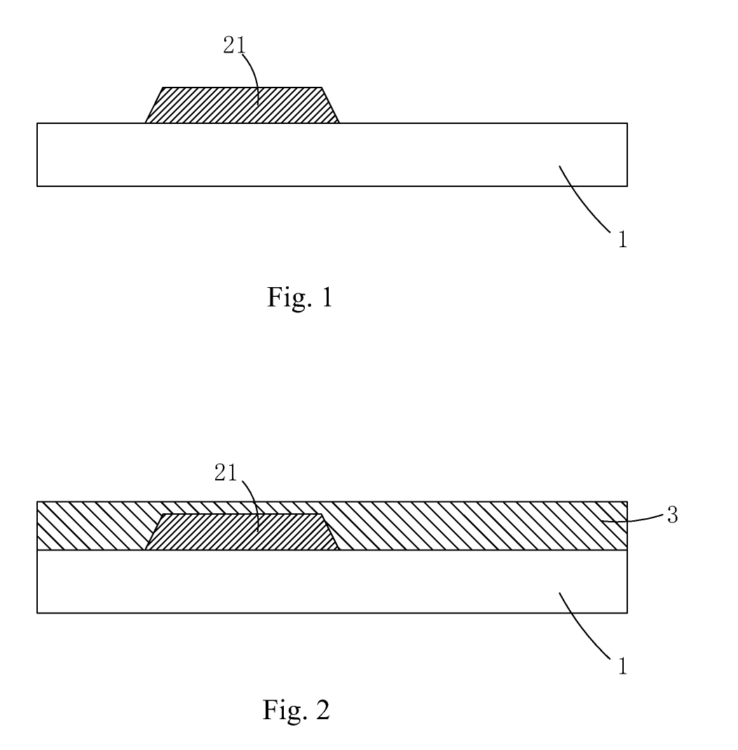

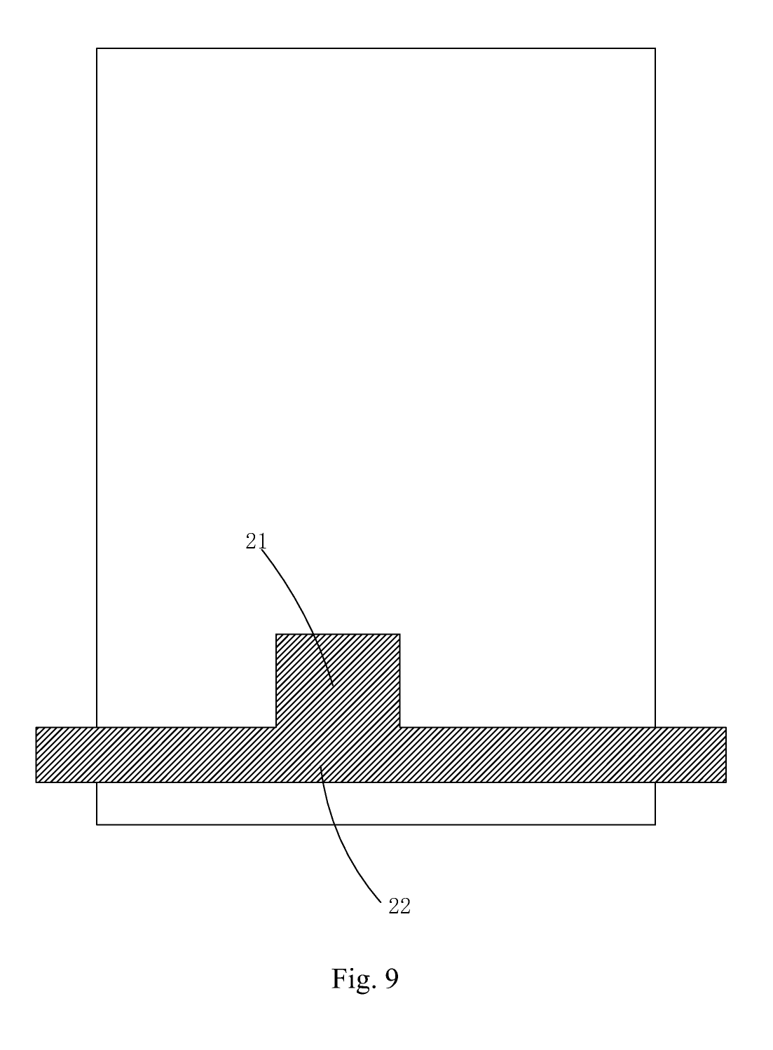

Step 1: referring to FIGS. 1 and 9, providing a base plate 1, depositing a first metal layer on the base plate 1, and using one mask to pattern the first metal layer so as to form a gate electrode 21 and a gate line 22 electrically connected with the gate electrode 21.

Specifically, the numbers of the gate electrode 21 and the gate line 22 are both plural and the plural gate electrodes 21 are arranged in an array and the plural gate lines 22 all extend in a horizontal direction and are arranged parallel to and spaced from each other. Each gate line 22 corresponds to and is electrically connected with a row of the gate electrodes 21. Preferably, the first metal layer comprises a material that comprises one or a combination of multiples ones of metallic materials including aluminum (Al), molybdenum (Mo), and copper (Cu). Preferably, the base plate 1 comprises a transparent glass plate or a transparent plastic plate.

Step 2: referring to FIG. 2, depositing a gate insulation layer 3 on the base plate 1, the gate electrode 21, and the gate line 22.

Specifically, the gate insulation layer 3 comprises a material that comprises one or a combination of multiples ones of silicon oxide (SiOx) and silicon nitride (SiNx).

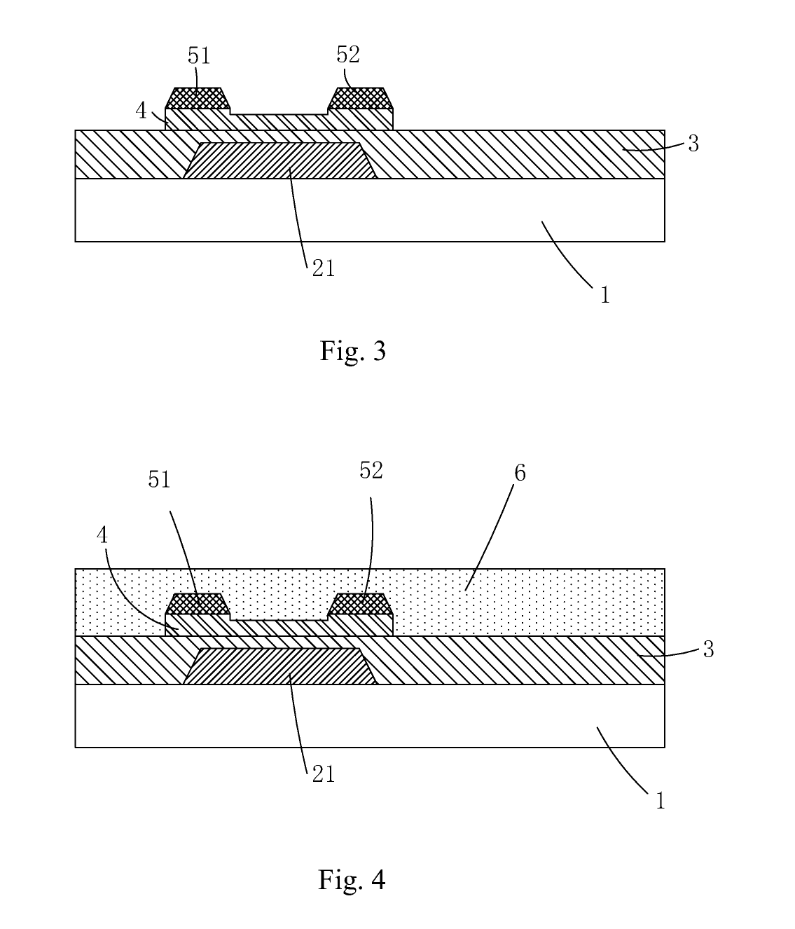

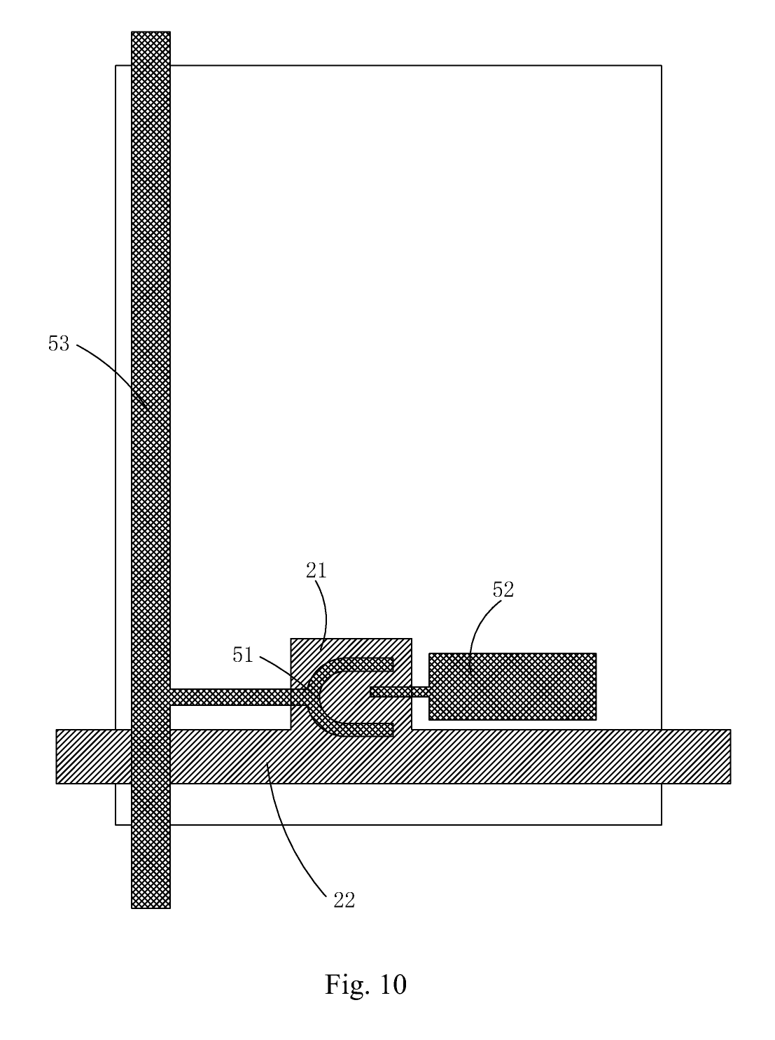

Step 3: referring to FIGS. 3 and 10, depositing a semiconductor layer and a second metal layer on the gate insulation layer 3 and using one mask to simultaneously pattern the semiconductor layer and the second metal layer with one mask so as to form an active layer 4 on the gate insulation layer 3 that is located above the gate electrode 21, a source electrode 51 and a drain electrode 52 that are respectively in contact engagement with two ends of the active layer 4, and a data line 53 electrically connected with the source electrode 51.

Specifically, Step 3 comprises:

Step 31: coating photoresist on the second metal layer, providing a gray tone mask (GTM) or a half tone mask (HTM) to subject the photoresist to patterning in order to remove a portion of the photoresist on a location of a channel zone of a TFT to be formed and remove all the photoresist located outside areas of the TFT to be formed and the data line, while preserving all the photoresist in areas of a source electrode and a drain electrode of the TFT to be formed and the data line;

Step 32: conducting a first etching operation to remove the second metal layer and the semiconductor layer that is not covered by the photoresist;

Step 33: conducting an ashing operation of the photoresist on the channel zone of the TFT to be formed to remove all the photoresist on the channel zone of the TFT to be formed;

Step 34: subsequently conducting a second etching operation to remove the second metal layer on the channel zone of the TFT to be formed to form the active layer 4, the source electrode 51 and the drain electrode 52 respectively in contact engagement with the two ends of the active layer 4, and the data line 53 electrically connection with the source electrode 51.

Specifically, the source electrode 51 and the drain electrode 52 of which the numbers each correspond to the number of the gate electrode 21 and are arranged in an array. The number of the data line 53 is plural and the plural data lines 53 are arranged to extend in a vertical direction and are parallel to and spaced from each other. Each data line 53 is electrically connected with a column of source electrodes 51. Preferably, the active layer 4 comprises a material that comprises amorphous silicon, poly-silicon, or an oxide semiconductor. The second metal layer comprises a material that comprises one or a combination of multiples ones of metal materials including aluminum, molybdenum, and copper.

Step 4: referring to FIG. 4, depositing a passivation layer 6 on the source electrode 51, the drain electrode 52, the data line 53, the active layer 4, and the gate insulation layer 3.

Specifically, the passivation layer 6 comprises a material that comprises one or a combination of multiple ones of silicon oxide and silicon nitride.

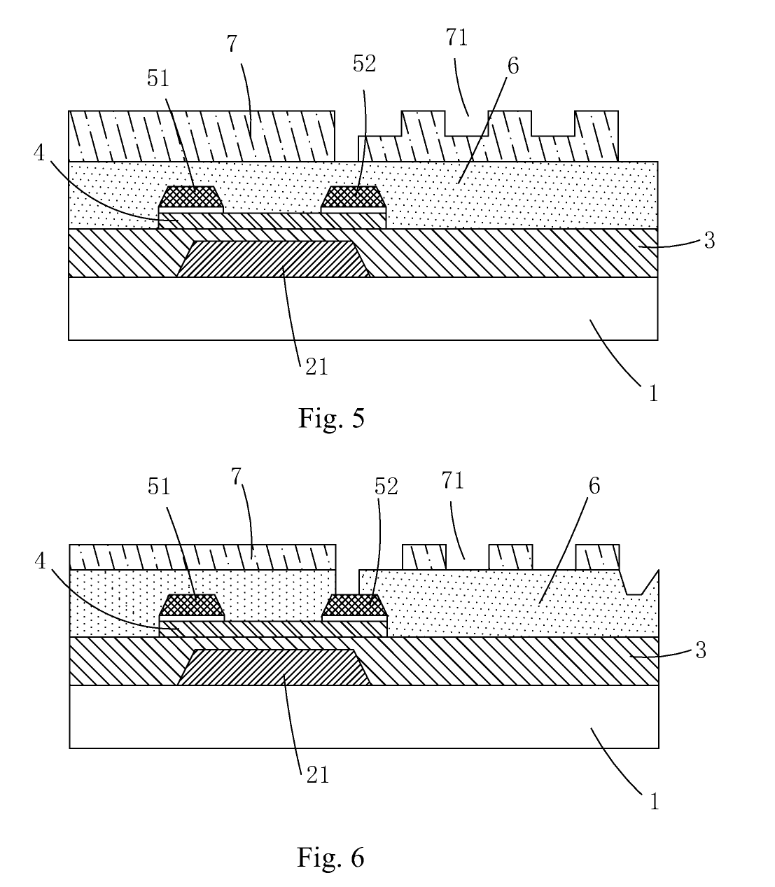

Step 5: referring to FIG. 5, coating photoresist on the passivation layer 6 to form a photoresist layer 7, using one mask to pattern the photoresist layer 7 to completely remove the photoresist layer 7 corresponding to and located above a part of the drain electrode 52 and a margin of an area of a pixel electrode to be formed and expose portions of the passivation layer 6 located above the part of the drain electrode 52 and the margin of the area of the pixel electrode to be formed and also to reduce a thickness of a portion of the photoresist layer 7 in the area of the pixel electrode to be formed to form photoresist grooves 71 extending in multiple different directions.

Specifically, Step 5 uses a half tone mask or a gray tone mask to conduct exposure of the photoresist layer 7, wherein the half tone mask or the gray tone mask comprises: a partially light-transmitting area, a non-light-transmitting area, and a completely light-transmitting area, wherein the partially light-transmitting area corresponds to an area of the photoresist layer 7 in which the photoresist grooves 71 are to be formed and the completely light-transmitting area is arranged to correspond to the portions of the photoresist layer 7 located above and corresponding to the part of the drain electrode 52 and the margin of the area of the pixel electrode to be formed, while an area other than the partially light-transmitting area and the completely light-transmitting area is entirely the non-light-transmitting area. The partially light-transmitting area is used to reduce the thickness of the photoresist layer 7 at a corresponding location and the completely light-transmitting area is used to completely remove the photoresist layer 7 at a corresponding location, while the photoresist layer 7 at a location corresponding to the non-light-transmitting area is completely preserved. It is appreciated that according to the property of the photoresist of being positive or negative, the locations of the non-light-transmitting area and the completely light-transmitting area may be switched with each other.

Preferably, the photoresist grooves 71 that extend in the multiple different directions are arranged to show a configuration of superimposition of a “cross” and a “saltire”, which comprises multiple photoresist grooves 71 extending respectively in directions that are angularly shifted by 45°, 135°, 225°, and 315° with respect to a horizontal direction.

Step 6: referring to FIG. 6, using the remaining photoresist layer 7 as a shield to conduct a first etching operation to completely remove the passivation layer 6 that is located above the drain electrode 52 and is not shielded by the photoresist layer 7 to expose the part of the drain electrode 52 and at the same time, also to partly remove the passivation layer 6 in the margin of the area of the pixel electrode to be formed to reduce a thickness of a part of the passivation layer 6 in the margin of the area of the pixel electrode to be formed, and subsequently conducting a first photoresist ashing operation to completely remove the photoresist layer 7 in each of the photoresist grooves 71 and reduce a thickness of the photoresist layer 7 on two sides of each of the photoresist grooves 71.

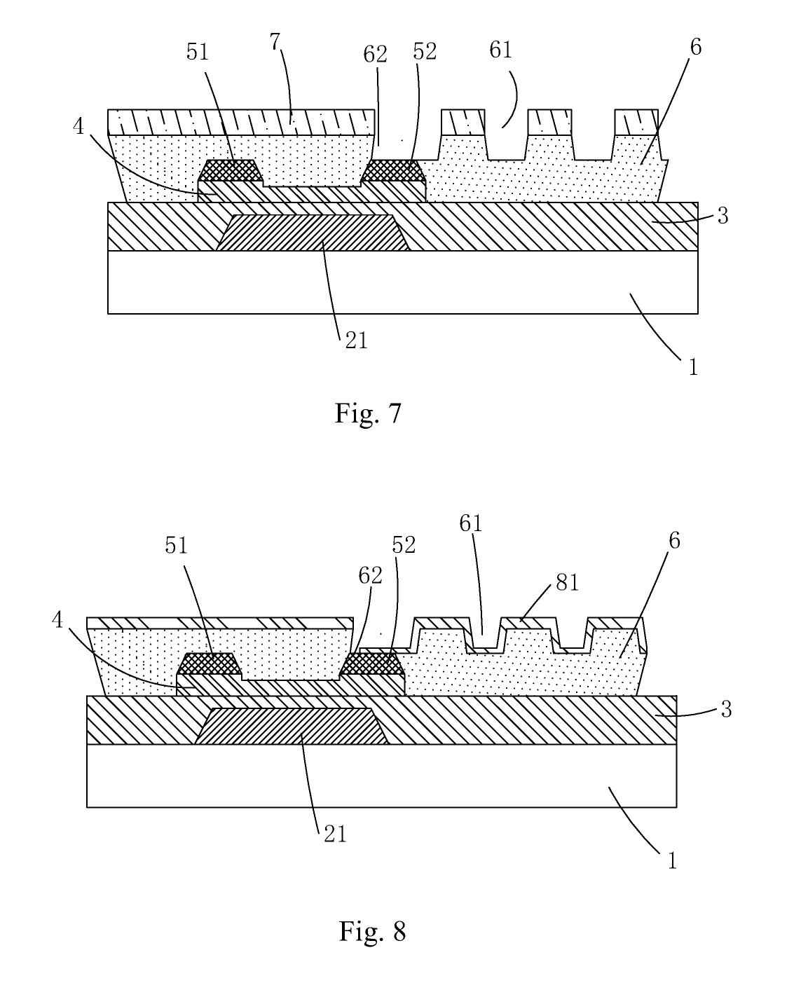

Step 7: referring to FIG. 7, using the remaining photoresist layer 7 as a shield to conduct a second etching operation to reduce a thickness of the passivation layer 6 in each of the photoresist grooves 71 so as to form passivation layer grooves 61 extending in multiple different directions and at the same time, to partly or completely remove the passivation layer 6 remaining in the margin of the area of the pixel electrode to be formed to form a pixel spacing groove 62 at the margin of the area of the pixel electrode to be formed.

Specifically, the passivation layer groove 61 has a configuration that corresponds to a configuration of the photoresist groove 71 and also shows an arrangement of superimposition of a “cross” and a “saltire”, which comprising passivation layer grooves 61 extending respectively in directions that are angularly shifted by 45°, 135°, 225°, and 315° with respect to a horizontal direction. In addition, the passivation layer 6 that is located above the drain electrode 52 in the pixel spacing groove 62 and at one side that is close to the source electrode 51 has a taper angle that is greater than 90 degrees, while the passivation layer 6 at one side that is distant from the source electrode 51 has a taper angle that is smaller than 90 degrees; the passivation layer on two sides of a portion of the pixel spacing groove 62 at a location other than being above the drain electrode 52 have a taper angle greater than 90 degrees.

Further, the amount of the remaining passivation layer 6 in the margin of the area of the pixel electrode to be formed that is removed by the second etching operation can be varied correspondingly according to a designed depth of the passivation layer groove 61 and can be, at most, completely removed. In case of complete removal, the depth of the passivation layer grooves 61 is greater than or equal to a thickness of the remaining passivation layer 6 in the margin of the area of the pixel electrode to be formed and of course, if the depth of the passivation layer groove 61 is less than the thickness of the remaining passivation layer 6 in the margin of the area of the pixel electrode to be formed, then the remaining passivation layer 6 in the margin of the area of the pixel electrode to be formed will not be completely removed.

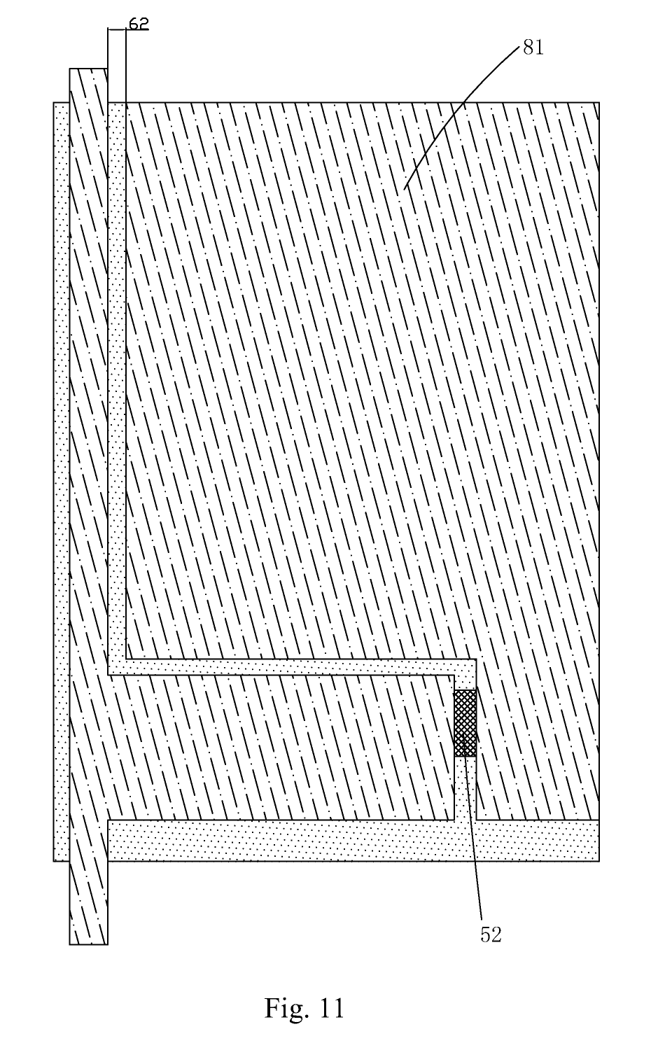

Step 8: referring to FIGS. 8 and 11, completely removing the remaining photoresist layer 7 and depositing a transparent conductive layer on the passivation layer 6 and the exposed drain electrode 52, wherein the transparent conductive layer is interrupted at the pixel spacing groove 62 during deposition to form a pixel electrode 81 in contact engagement with the drain electrode 52, the pixel electrode 81 showing a corrugated configuration in compliance with the passivation layer grooves 61.

Specifically, the pixel electrode 81 is formed in compliance with the passivation layer grooves 61 as an entire sheet of pixel electrode having a surface showing a corrugated configuration corresponding to the configuration of superimposition of a “cross” and a “saltire” of the passivation layer groove 61, providing an effect of control similar to that achieved with slit pixel electrodes having a configuration of superimposition of a “cross” and a “saltire” adopted in a multi-domain vertical alignment (VA) liquid crystal display panel. Since the passivation layer has a relatively large taper angle at least at one side of the pixel spacing groove 62, the transparent conductive layer may naturally break open at the location of the pixel spacing groove 62 during deposition so that the transparent conductive layer located on the data line 53, the gate line 22, the gate electrode 21, and the source electrode 51 is separated from the pixel electrode 81, preventing influence on a normal operation of the pixel electrode 81.

Further, in Step 8, the formation of the pixel electrode 81 requires no patterning conducted with a mask and also requires no ITO lift-off for the material thereof so as to save one mask and also prevent increased difficulty of the manufacturing process, and also ensure the display performance of the pixel electrode 81 so manufactured is the same as the display performance of a pixel electrode manufactured through exposure.

Preferably, in Step 8, the transparent conductive layer comprises a material that comprises indium tin oxides (ITO).

In summary, the present invention provides a TFT substrate manufacturing method, which uses a half tone mask or a gray tone mask to pattern a passivation layer so that a pixel electrode via and a groove-patterned passivation layer can be formed with one mask. And, a transparent conductive material can be deposited on and in compliance with the passivation layer to form a pixel electrode. The pixel electrode requires no mask for patterning, and entire manufacture of a TFT substrate requires only three masks, without the need of indium tin oxide lift-off technique, making the difficulty of manufacturing low and efficiency high.

Based on the description given above, those having ordinary skills in the art may easily contemplate various changes and modifications of he technical solution and the technical ideas of the present invention. All these changes and modifications are considered belonging to the protection scope of the present invention as defined in the appended claims.

What is claimed is:

1. A thin film transistor (TFT) substrate manufacturing method, comprising the following steps:
Step 1: providing a base plate, depositing a first metal layer on the base plate, and using one mask to pattern the first metal layer so as to form a gate electrode and a gate line electrically connected with the gate electrode;
Step 2: depositing a gate insulation layer on the base plate, the gate electrode, and the gate line;
Step 3: depositing a semiconductor layer and a second metal layer on the gate insulation layer and using one mask to simultaneously pattern the semiconductor layer and the second metal layer with one mask so as to form an active layer on the gate insulation layer that is located above the gate electrode, a source electrode and a drain electrode that are respectively in contact engagement with two ends of the active layer, and a data line electrically connected with the source electrode;
Step 4: depositing a passivation layer on the source electrode, the drain electrode, the data line, the active layer, and the gate insulation layer;
Step 5: coating photoresist on the passivation layer to form a photoresist layer, using one mask to pattern the photoresist layer to completely remove the photoresist layer corresponding to and located above a part of the drain electrode and a margin of an area of a pixel electrode to be formed and expose portions of the passivation layer located above the part of the drain electrode and the margin of the area of the pixel electrode to be formed and also to reduce a thickness of a portion of the photoresist layer in the area of the pixel electrode to be formed to form photoresist grooves extending in multiple different directions;
Step 6: using the remaining photoresist layer as a shield to conduct a first etching operation to completely remove the passivation layer that is located above the drain electrode and is not shielded by the photoresist layer to expose the part of the drain electrode and at the same time, also to partly remove the passivation layer in the margin of the area of the pixel electrode to be formed to reduce a thickness of a part of the passivation layer in the margin of the area of the pixel electrode to be formed, and subsequently conducting a first photoresist ashing operation to completely remove the photoresist layer in each of the photoresist grooves and reduce a thickness of the photoresist layer on two sides of each of the photoresist grooves;
Step 7: using the remaining photoresist layer as a shield to conduct a second etching operation to reduce a thickness of the passivation layer in each of the photoresist grooves so as to form passivation layer grooves extending in multiple different directions and at the same time, to partly or completely remove the passivation layer remaining in the margin of the area of the pixel electrode to be formed to form a pixel spacing groove at the margin of the area of the pixel electrode to be formed; and
Step 8: completely removing the remaining photoresist layer and depositing a transparent conductive layer on the passivation layer and the exposed drain electrode, wherein the transparent conductive layer is interrupted at the pixel spacing groove during deposition to form a pixel electrode in contact engagement with the drain electrode, the pixel electrode showing a corrugated configuration in compliance with the passivation layer grooves.

2. The TFT substrate manufacturing method as claimed in claim 1, wherein Step 3 comprises:
Step 31: coating photoresist on the second metal layer, providing a gray tone mask or a half tone mask to subject the photoresist to patterning in order to remove a portion of the photoresist on a location of a channel zone of a TFT to be formed and remove all the photoresist located outside areas of the TFT to be formed and the data line, while preserving all the photoresist in areas of a source electrode and a drain electrode of the TFT to be formed and the data line;
Step 32: conducting a first etching operation to remove the second metal layer and the semiconductor layer that is not covered by the photoresist;
Step 33: conducting an ashing operation of the photoresist on the channel zone of the TFT to be formed to remove all the photoresist on the channel zone of the TFT to be formed; and
Step 34: subsequently conducting a second etching operation to remove the second metal layer on the channel zone of the TFT to be formed to form the active layer, the source electrode and the drain electrode respectively in contact engagement with the two ends of the active layer, and the data line electrically connection with the source electrode.

3. The TFT substrate manufacturing method as claimed in claim 1, wherein the mask used in Step 5 for exposure of the photoresist layer is a gray tone mask or a half tone mask.

4. The TFT substrate manufacturing method as claimed in claim 1, wherein the active layer comprises a material that comprises amorphous silicon, poly-silicon, or an oxide semiconductor.

5. The TFT substrate manufacturing method as claimed in claim 1, wherein the passivation layer that is located above the drain electrode in the pixel spacing groove and at one side that is close to the source electrode has a taper angle that is greater than 90 degrees, while the passivation layer at one side that is distant from the source electrode has a taper angle that is smaller than 90 degrees; the passivation layer on two sides of a portion of the pixel spacing groove at a location other than being above the drain electrode have a taper angle greater than 90 degrees.

6. The TFT substrate manufacturing method as claimed in claim 1, wherein in Step 8, the transparent conductive layer comprises a material that comprises indium tin oxide (ITO).

7. The TFT substrate manufacturing method as claimed in claim 1, wherein the first metal layer and the second metal layer comprise a material that comprises one or a combination of multiple ones of aluminum, molybdenum, and copper.

8. The TFT substrate manufacturing method as claimed in claim 1, wherein the gate insulation layer and the passivation layer comprise a material that comprises one or a combination of multiple ones of silicon oxide and silicon nitride.

9. The TFT substrate manufacturing method as claimed in claim 1, wherein the base plate comprises a transparent glass plate or a transparent plastic plate.

10. A thin film transistor (TFT) substrate manufacturing method, comprising the following steps:
Step 1: providing a base plate, depositing a first metal layer on the base plate, and using one mask to pattern the first metal layer so as to form a gate electrode and a gate line electrically connected with the gate electrode;
Step 2: depositing a gate insulation layer on the base plate, the gate electrode, and the gate line;
Step 3: depositing a semiconductor layer and a second metal layer on the gate insulation layer and using one mask to simultaneously pattern the semiconductor layer and the second metal layer with one mask so as to form an active layer on the gate insulation layer that is located above the gate electrode, a source electrode and a drain electrode that are respectively in contact engagement with two ends of the active layer, and a data line electrically connected with the source electrode;
Step 4: depositing a passivation layer on the source electrode, the drain electrode, the data line, the active layer, and the gate insulation layer;
Step 5: coating photoresist on the passivation layer to form a photoresist layer, using one mask to pattern the photoresist layer to completely remove the photoresist layer corresponding to and located above a part of the drain electrode and a margin of an area of a pixel electrode to be formed and expose portions of the passivation layer located above the part of the drain electrode and the margin of the area of the pixel electrode to be formed and also to reduce a thickness of a portion of the photoresist layer in the area of the pixel electrode to be formed to form photoresist grooves extending in multiple different directions;
Step 6: using the remaining photoresist layer as a shield to conduct a first etching operation to completely remove the passivation layer that is located above the drain electrode and is not shielded by the photoresist layer to expose the part of the drain electrode and at the same time, also to partly remove the passivation layer in the margin of the area of the pixel electrode to be formed to reduce a thickness of a part of the passivation layer in the margin of the area of the pixel electrode to be formed, and subsequently conducting a first photoresist ashing operation to completely remove the photoresist layer in each of the photoresist grooves and reduce a thickness of the photoresist layer on two sides of each of the photoresist grooves;
Step 7: using the remaining photoresist layer as a shield to conduct a second etching operation to reduce a thickness of the passivation layer in each of the photoresist grooves so as to form passivation layer grooves extending in multiple different directions and at the same time, to partly or completely remove the passivation layer remaining in the margin of the area of the pixel electrode to be formed to form a pixel spacing groove at the margin of the area of the pixel electrode to be formed; and
Step 8: completely removing the remaining photoresist layer and depositing a transparent conductive layer on the passivation layer and the exposed drain electrode, wherein the transparent conductive layer is interrupted at the pixel spacing groove during deposition to form a pixel electrode in contact engagement with the drain electrode, the pixel electrode showing a corrugated configuration in compliance with the passivation layer grooves;
wherein the mask used in Step 5 for exposure of the photoresist layer is a gray tone mask or a half tone mask; and
wherein the active layer comprises a material that comprises amorphous silicon, poly-silicon, or an oxide semiconductor.

11. The TFT substrate manufacturing method as claimed in claim 10, wherein Step 3 comprises:
Step 31: coating photoresist on the second metal layer, providing a gray tone mask or a half tone mask to subject the photoresist to patterning in order to remove a portion of the photoresist on a location of a channel zone of a TFT to be formed and remove all the photoresist located outside areas of the TFT to be formed and the data line, while preserving all the photoresist in areas of a source electrode and a drain electrode of the TFT to be formed and the data line;
Step 32: conducting a first etching operation to remove the second metal layer and the semiconductor layer that is not covered by the photoresist;
Step 33: conducting an ashing operation of the photoresist on the channel zone of the TFT to be formed to remove all the photoresist on the channel zone of the TFT to be formed; and
Step 34: subsequently conducting a second etching operation to remove the second metal layer on the channel zone of the TFT to be formed to form the active layer, the source electrode and the drain electrode respectively in contact engagement with the two ends of the active layer, and the data line electrically connection with the source electrode.

12. The TFT substrate manufacturing method as claimed in claim 10, wherein the passivation layer that is located above the drain electrode in the pixel spacing groove and at one side that is close to the source electrode has a taper angle that is greater than 90 degrees, while the passivation layer at one side that is distant from the source electrode has a taper angle that is smaller than 90 degrees; the passivation layer on two sides of a portion of the pixel spacing groove at a location other than being above the drain electrode have a taper angle greater than 90 degrees.

13. The TFT substrate manufacturing method as claimed in claim 10, wherein in Step 8, the transparent conductive layer comprises a material that comprises indium tin oxide (ITO).

14. The TFT substrate manufacturing method as claimed in claim 10, wherein the first metal layer and the second metal layer comprise a material that comprises one or a combination of multiple ones of aluminum, molybdenum, and copper.

15. The TFT substrate manufacturing method as claimed in claim 10, wherein the gate insulation layer and the passivation layer comprise a material that comprises one or a combination of multiple ones of silicon oxide and silicon nitride.

16. The TFT substrate manufacturing method as claimed in claim 10, wherein the base plate comprises a transparent glass plate or a transparent plastic plate.
